(19) United States
(12) Patent Application Publication
(10) Pub. No.: US 2024/0153883 A1
(43) Pub. Date: May 9, 2024

(54) DEVICE INCLUDING OVERLAY TARGET STRUCTURE

(71) Applicant: SAMSUNG ELECTRONICS CO., LTD., Suwon-si (KR)

(72) Inventors: Seunghoon HAN, Suwon-si (KR); Doowon KWON, Hwaseong-si (KR); Taeyeong KIM, Hwaseong-si (KR); Minho JANG, Hwaseong-si (KR); Sohye CHO, Hwaseong-si (KR); Haesung KIM, Suwon-si (KR); Hyeonsoo PARK, Suwon-si (KR)

(73) Assignee: SAMSUNG ELECTRONICS CO., LTD., Suwon-si (KR)

(21) Appl. No.: 18/387,729

(22) Filed: Nov. 7, 2023

(30) Foreign Application Priority Data
Nov. 7, 2022 (KR) 10-2022-0147373

(51) Int. Cl. H01L 23/544; H01L 21/66

(52) U.S. Cl. CPC H01L 23/544; H01L 22/12; H01L 2223/54426

(57) ABSTRACT

Provided is a device including a substrate and an overlay target structure provided on the substrate, the overlay target structure includes a first alignment key having a plurality of line masks having a first width and arranged at a first pitch, a second alignment key having a plurality of line masks having a second width and arranged at a second pitch, and a nanostructure layer arranged between the first alignment key and the second alignment key, and including a plurality of nanostructures having widths less than or equal to the first width and the second width, and arranged at a pitch less than the first pitch and the second pitch.

### CROSS-REFERENCE TO RELATED APPLICATION

This application is based on and claims priority under 35 U.S.C. § 119 to Korean Patent Application No. 10-2022-0147373, filed on Nov. 7, 2022, in the Korean Intellectual Property Office, the disclosure of which is incorporated by reference herein in its entirety.

### BACKGROUND

### 1. Field

Example embodiments of the present disclosure relate to a device including an overlay target structure.

### 2. Description of Related Art

The degree of integration of various integrated circuit devices including a memory, a driving integrated circuit (IC), a logic device, an image sensor, and the like is increasing, and thus, the size of electronic elements provided therein is decreasing. In addition, optical elements may be made flat on a wafer substrate in a nanostructure.

These electronic and optical elements formed on different substrates may be packaged in a single package by using an alignment mark provided on each substrate. The alignment marks include patterns that transmit and reflect light, and the degree of alignment may be confirmed by detecting transmission, reflection, and scattering patterns according to an overlay form of facing alignment marks.

In order to improve the alignment precision, the shape dimensions of the patterns provided in the alignment marks are reduced, however it is difficult to implement a sub-micron level, for example, 100 nm level of measurement precision, due to an optical resolution limit.

### SUMMARY

One or more example embodiments provide an alignment key capable of increasing the alignment precision when manufacturing an electronic device and a device including the same.

Additional aspects will be set forth in part in the description which follows and, in part, will be apparent from the description, or may be learned by practice of the example embodiments of the disclosure.

According to an aspect of an example embodiment, there is provided a device including a substrate, and an overlay target structure provided on the substrate, wherein the overlay target structure includes a first alignment key having a first pattern that includes a plurality of first line masks provided at a first pitch in a second direction, each first line mask of the plurality of first line masks having a first width in the second direction and a first length in a first direction perpendicular to the second direction, a second alignment key spaced apart from the first alignment key in a third direction perpendicular to the first direction and the second direction to face the first alignment key, and having a second pattern that includes a plurality of second line masks provided at a second pitch in the second direction, each second line mask of the plurality of second line masks having a second width in the second direction and a second length in the first direction, and a nanostructure layer including a plurality of nanostructures between the first alignment key and the second alignment key, each nanostructure of the plurality of nanostructures having a width that is less than or equal to the first width and the second width and being provided at a pitch that is less than the first pitch and the second pitch.

The plurality of nanostructures may include a metal material or a dielectric material.

Each nanostructure of the plurality of nanostructures may have a cylindrical shape or polygonal pillar shape, and wherein a cross-section diameter or one side of each nanostructure of the plurality of nanostructures may be less than or equal to the first width and the second width.

The plurality of nanostructures may be provided in two or more layers in the third direction.

An interval between adjacent layers among the two or more layers may be less than or equal to 100 nm.

Each first line mask of the plurality of first line masks and each second line mask of the plurality of second line masks includes a metal material.

The first pattern may include a plurality of first groups, each first group of the plurality of first groups including the plurality of first line masks, and the plurality of first groups may be provided in the first direction, and adjacent groups of the plurality of first groups are offset at a predetermined interval in the second direction with respect to each other.

The plurality of first groups may be provided in the first direction and gradually offset in the second direction.

The predetermined interval may be less than or equal to ½ of the first width.

The predetermined interval may be less than or equal to 100 nm.

A size of each first group of the plurality of first groups in the first direction may be greater than or equal to 1 μm.

The first alignment key may further include a third pattern on a same layer as the first pattern, the third pattern including a plurality of third line masks provided at a third pitch in the first direction, each third line mask of the plurality of third line masks having a third length in the second direction and a third width in the first direction, and the second alignment key may further include a fourth pattern on a same layer as the second pattern, the fourth pattern including a plurality of fourth line masks provided at a fourth pitch in the first direction, each fourth line mask of the plurality of fourth line masks having a fourth length in the second direction and a fourth width in the first direction.

The first pattern may include a plurality of first groups, each first group of the plurality of first groups including the plurality of first line masks, the plurality of first groups may be provided in the first direction, and adjacent groups of the plurality of first groups may be offset at a predetermined interval in the second direction with respect to each other.

The third pattern may include a plurality of third groups, each third group of the plurality of third groups including the plurality of third line masks, and the plurality of third groups may be provided in the second direction, and adjacent groups of the plurality of third groups may be offset at a predetermined interval in the first direction with respect to each other.

The plurality of first groups included in the first pattern may form a first set, and the plurality of third groups included in the third pattern key may form a third set, the first alignment key may further include a second set including a plurality of second groups having a configuration same as the first set and a fourth set including a plurality of fourth groups having a configuration same as the third set, and a trajectory in which the plurality of first groups included in the first set, the plurality of second groups included in the second set, the plurality of third groups included in the third set, and the plurality of fourth groups included in the fourth set are provided is rectangular.

The first alignment key may further include a mask pattern in a central portion of a rectangular trajectory formed by the first set, the second set, the third set, and the fourth set.

According to another aspect of an example embodiment, there is provided a device including a substrate, a first alignment key having a first pattern that includes a plurality of first line masks provided at a first pitch in a second direction, each first line mask of the plurality of first line masks having a first width in the second direction and a first length in a first direction perpendicular to the second direction, and a nanostructure layer including a plurality of nanostructures provided on the first alignment key, each nanostructure of the plurality of nanostructures having a width that is less than the first width and provided at a pitch less than the first pitch.

The first alignment key may further include a third pattern on a same layer as the first pattern, and includes a plurality of third line masks provided at a third pitch in the first direction, each third line mask of the plurality of third line masks having a third length in the second direction and a third width in the first direction.

The first pattern may include a plurality of first groups, each first group of the plurality of first groups including the plurality of first line masks, the plurality of first groups may be provided in the first direction, and adjacent groups of the plurality of first groups may be offset at a predetermined interval in the second direction with respect to each other.

The third pattern may include a plurality of third groups, each third group of the plurality of third groups having the plurality of third line masks, the plurality of third groups may be provided in the second direction, and adjacent groups of the plurality of third groups may be offset at a predetermined interval in the first direction with respect to each other.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view showing a structure of a device according to an example embodiment;

FIGS. 2A, 2B, and 2C are plan views illustrating respectively structures of a first alignment key, a second alignment key, and a nanostructure layer of an overlay target structure included in a device according to an example embodiment;

FIGS. 3 and 4 are computer simulation diagrams showing classification of the transmittance of incident light according to the alignment states of first and second alignment keys of an overlay target structure when manufacturing a device according to an example embodiment;

FIG. 5 is a cross-sectional view illustrating a structure of a device according to another example embodiment;

FIG. 6 is a cross-sectional view illustrating an example of an overlay target structure provided in an device according to another example embodiment;

FIGS. 7A and 7B are plan views illustrating respectively structures of a first alignment key and a second alignment key of the overlay target structure of FIG. 6;

FIG. 8 is a plan view illustrating an overlay target structure provided in a device according to another example embodiment;

FIGS. 9A and 9B are detailed plan views illustrating respectively structures of a first alignment key and a second alignment key of the overlay target structure of FIG. 8;

FIG. 10 is a plan view illustrating an overlay target structure provided in a device according to another example embodiment;

FIGS. 11A and 11B are plan views illustrating a first alignment key and a second alignment key of an overlay target structure provided in a device according to another example embodiment, respectively;

FIGS. 12, 13, and 14 are plan views illustrating overlay target structures provided in a device according to other example embodiments, respectively; and

FIGS. 15, 16, 17, and 18 are diagrams illustrating examples in which overlay target structures according to example embodiments are used.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, example embodiments will be described in detail with reference to the accompanying drawings. The embodiments described below are merely exemplary, and various modifications are possible from these embodiments. In the following drawings, the same reference numerals refer to the same components, and the size of each component in the drawings may be exaggerated for clarity and convenience of description.

Hereinafter, the term “upper portion” or “on” may also include “to be present above on a non-contact basis” as well as “to be on the top portion in directly contact with”.

Terms such as first and second may be used to describe various components, but are used only for the purpose of distinguishing one component from another component. These terms do not limit the difference in the materials or structures of the components.

Singular expressions include plural expressions unless they are explicitly meant differently in context. In addition, when a part “includes” a component, this means that it may include more other components, rather than excluding other components, unless otherwise stated.

Further, the terms “unit”, “module” or the like mean a unit that processes at least one function or operation, which may be implemented in hardware or software or implemented in a combination of hardware and software.

The use of the term “the” and similar indicative terms may correspond to both singular and plural.

Steps constituting the method may be performed in an appropriate order unless there is a clear statement that the steps should be performed in the order described. In addition, the use of all illustrative terms (e.g., etc.) is simply intended to detail technical ideas and, unless limited by the claims, the scope of rights is not limited due to the terms.

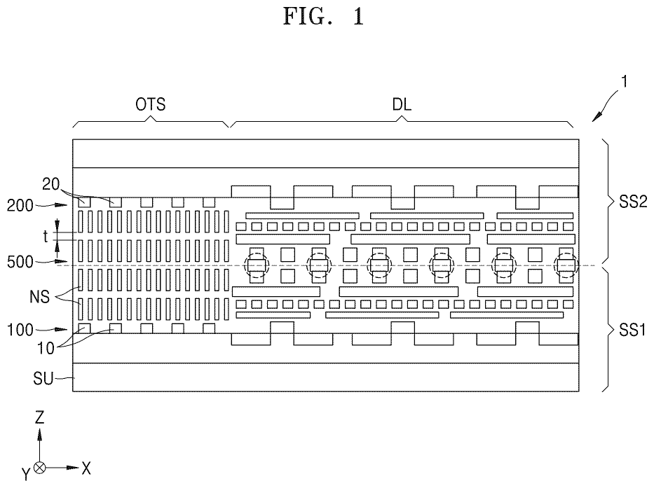

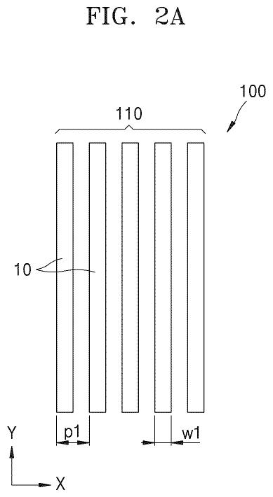

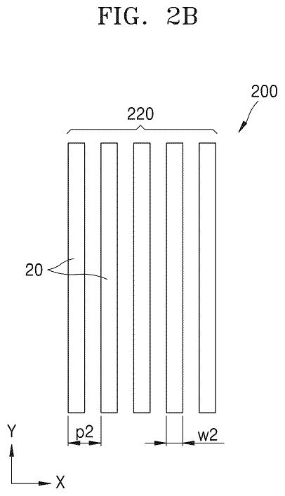

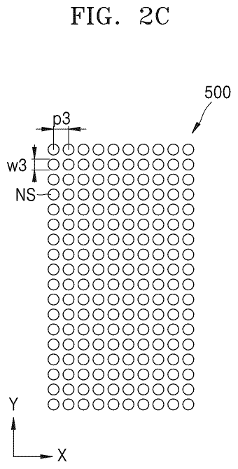

FIG. 1 is a cross-sectional view showing a structure of a device according to an example embodiment, and FIGS. 2A, 2B, and 2C are plan views illustrating respective structures of a first alignment key, a second alignment key, and a nanostructure layer of an overlay target structure included in a device according to an example embodiment.

The device 1 includes a substrate SU and an overlay target structure OTS arranged on the substrate SU. The overlay target structure OTS includes a first alignment key 100, a second alignment key 200, and a nanostructure layer 500 arranged between the first alignment key 100 and the second alignment key 200.

The overlay target structure OTS is used to precisely couple two separately manufactured electronic devices. The overlay target structure OTS may be provided to be divided into two parts in the two substrate structures SS1 and SS2 to be coupled. The device 1 is an example of a structure in which, for example, a substrate structure SS1 having the first alignment key 100 and a part of the nanostructure layer 500, and a substrate structure SS2 having the second alignment key 200 and another part of the nanostructure layer 500 are combined. When combining two substrate structures SS1 and SS2, the degree of misalignment of the two substrate structures SS1 and SS2 may be measured from the transmission or reflection pattern after light passes through the overlay target structure OTS. Accordingly, it is possible to determine whether the misalignment of the two substrate structures SS1 and SS2 are good or bad. Thus, considering the measured results, the two substrate structures SS1 and SS2 may be aligned to their desired positions, or the conditions of bonding the two substrate structures SS1 and SS2 may be corrected. After the two substrate structures SS1 and SS2 are aligned to desired positions, they are directly bonded to each other. As illustrated by dotted circles, the two substrate structures SS1 and SS2 may be, for example, metal bonded or hybrid bonded. The shape in which the overlay target structure OTS is divided into two parts in the two substrate structures SS1 and SS2 is not limited to the shape shown in FIG. 1. For example, the nanostructure layer 500 may be provided only in one of the two substrate structures SS1 and SS2.

The device 1 consisting of a combination of two substrate structures SS1 and SS2 includes a device layer DL made of, for example, an insulating pattern, a semiconductor pattern, a metal pattern, etc. The device 1 may be various semiconductor devices, for example, a memory device, a logic device, an image sensor, an integrated circuit device, or the like, and may be a flat nanostructure-based optical device formed on a wafer substrate, but embodiments are not limited thereto.

Referring to FIG. 2A, the first alignment key 100 includes a first pattern 110 consisting of a plurality of line masks 10. The line masks 10 have a length direction in a first direction (Y direction) and a width in a second direction (X direction), and arranged in the second direction (X direction). The plurality of line masks 10 may have a first width w1 and may be arranged at a first pitch p1.

Referring to FIG. 2B, the second alignment key 200 includes a second pattern 220 consisting of a plurality of line masks 20, similar to the first alignment key 100. The line masks 20 have a length direction in a first direction (Y direction) and a width in a second direction (X direction), and arranged in the second direction (X direction). The plurality of line masks 20 may have a second width w2 and be arranged at a second pitch p2.

The first width w1, the first pitch p1, the second width w2, and the second pitch p2 may have a sub-wavelength, that is, may be less than a wavelength of a light used to measure alignment. The central wavelength of the wavelength band of light to be used will hereinafter be referred to as a reference wavelength. The reference wavelength may be, for example, approximately 1 μm. For example, w1 and w2 may be in a range of about 100 nm to about 300 nm, and p1 and p2 may be in a range of about 200 nm to about 600 nm, but these are only examples and embodiments are not limited thereto. The widths w1 and w2 may be the same or different from each other. The pitches p1 and p2 may also be the same or different from each other.

The line masks 10 of the first alignment key 100 and the line masks 20 of the second alignment key 200 may be made of metal materials. For example, the metal materials may include copper (Cu), tungsten (W), titanium (Ti), platinum (Pt), nickel (Ni), aluminum (Al), iridium (Ir), chromium (Cr), ruthenium (Ru), gold (Au), silver (Ag), molybdenum (Mo), titanium nitride (TiN), tantalum nitride (TaN), or tungsten nitride (WN). The material of the line masks 10 and 20 may be made of the same metal material as that of the metal pattern of the device layer DL located on the same layer as each of the line masks 10 and 20. The line masks 10 of the first alignment key 100 and the line masks 20 of the second alignment key 200 may be made of different metal materials. Each of the line masks 10 may include a plurality metal materials. Each of the line masks 10 may include a plurality of metal layers. The plurality of metal layers may be arranged in a direction perpendicular to the Z direction. Each of the line masks 20 may include a plurality metal materials. Each of the line masks 20 may include a plurality of metal layers. The plurality of metal layers may be arranged in a direction perpendicular to the Z direction.

When the metal material has a structure of not larger than the wavelength of incident light, it has a property of forming a surface plasmon, and in connection with this, the transmission and reflection patterns of light transmitted through the overlay target structure OTS vary according to the alignment shapes of the first alignment key 100 and the second alignment key 200. The measurement of the misalignment state of the line masks 10 and 20 with the illustrated sub-wavelength shape dimension requires approximately 10 nm to 200 nm of measurement precision, and it may be difficult to image the misalignment state by a general optical system due to a light diffraction limit.

The overlay target structure OTS according to an example embodiment includes a nanostructure layer 500 arranged between the first alignment key 100 and the second alignment key 200, and sub-wavelength imaging of a misaligned state between the first alignment key 100 and the second alignment key 200 may be possible by the nanostructure layer 500.

Referring to FIG. 2C, the nanostructure layer 500 includes a plurality of nanostructures NS. The plurality of nanostructures NS may be arranged at an arrangement pitch p3 less than the first pattern 110 and the second pattern 120, and the arrangement may have, for example, a rectangular lattice, a hexagonal lattice, or the like on a horizontal plane. The plurality of nanostructures NS may have a width w3 less than those of the line masks 10 of the first pattern 110 and the line masks 20 of the second pattern 210. The nanostructures NS may include a metal or dielectric material or a semiconductor material. The nanostructures NS may include various metal materials, similar to the first alignment key (100) and the second alignment key 200, or may include c-Si, p-Si, a-Si, III-V group compound semiconductors gallium arsenide (GaAs), gallium phosphide (GaP), gallium nitride (GaN), etc., silicon carbide (SiC), titanium oxide (TiO₂), or silicon nitride (SiN). The nanostructures NS may have a cylindrical or polygonal pillar shape. As illustrated in FIG. 2C, the nanostructures NS may have a cylindrical shape having a cross-sectional diameter w3. The nanostructures NS are not limited thereto, and may have a polygonal pillar shape in which the length of one side of the cross-section is w3. The width w3 may be less than or equal to w1 and w2, and the pitch p3 may be less than or equal to p1 and p2. For example, p3 may be about ½ or less of the reference wavelength. For example, p3 may be approximately 350 nm or less. The height of the nanostructure NS, that is, the thickness in the stacking direction (Z direction), may be ¼ or more of the reference wavelength, for example, 250 nm or more. The nanostructures NS may have an aspect ratio of about 1 or more, which is a ratio of a height to a width. However, this is only an example, and the height of the nanostructure NS is not particularly limited.

Each of the plurality of nanostructures NS may include a plurality of metal materials. Each of the plurality of nanostructures NS may include a plurality of metal layers. The plurality of metal layers may be arranged along a radial direction. Each of the plurality of nanostructures NS may include a plurality of dielectric materials. Each of the plurality of nanostructures NS may include a plurality of dielectric layers. The plurality of dielectric layers may be arranged along a radial direction.

The nanostructure layer 500 may include a plurality of layers. The nanostructure layer 500 may include a plurality of layers arranged in a third direction (Z direction) perpendicular to the first direction (Y direction) and the second direction (X direction). For example, the nanostructures NS may be arranged between the first alignment key 100 and the second alignment key 200 to form different layers. Although illustrated as four layers in FIG. 1, embodiments are not limited thereto, and the nanostructures NS may be arranged in one layer or other plurality of layers. When the nanostructures NS are arranged in a plurality of layers, the nanostructures NS forming different layers may have different shapes and may be arranged in different pitches. FIG. 2C is a plan view showing any one layer of the nanostructure layer 500, for example, the nanostructure NS of the other layer may have a cylindrical shape having different diameters, or have a polygonal pillar shape, and may have a periodic arrangement different from that of FIG. 2C. Various widths w3 less than or equal to the widths w1 and w2 of the line masks 10 and 20 provided in the first alignment key 100 and the second alignment key 200 may be applied to nanostructures NS provided in different layers, and various arrangement pitches p3, which are less than the arrangement pitches p1 and p2 of the line masks 10 and 20, may be applied to the arrangement of nanostructures NS provided in different layers. In addition, heights of nanostructures NS provided in different layers may be different from each other. In the cross-sectional view of FIG. 1, the nanostructures NS facing each other in different layers are illustrated as being aligned with each other, but embodiments are not limited thereto and may be arranged to be misaligned.

The regions between the nanostructures NS in the nanostructure layer 500 may be filled with an insulating material. The insulating material may include, for example, SU-8, polymethyl methacrylate (PMMA), organosilicate glass (SiCOH), silicon carbon-nitride (SiCN), silicon oxide (SiO₂), or SOG. When the nanostructures NS are formed of a dielectric material or a semiconductor material, the insulating material may have a refractive index less than those of the nanostructures NS. When the nanostructure layers 500 are formed of a plurality of layers, an interval between adjacent layers, that is, a thickness t of a region in which the nanostructures NS are not arranged in a horizontal direction (X direction or Y direction) in the nanostructure layers 500 may be set to be less than a predetermined reference value. For example, the thickness t may be about 1/10 or less of the reference wavelength. The thickness t may be approximately 100 nm or less. When the nanostructure layer 500 is formed of a plurality of layers, intervals between adjacent layers may be different from each other. For example, an interval between the first layer and the second layer and an interval between the second layer and the third layer may be different.

Although FIG. 2C illustrates the nanostructures NS are arranged in a square lattice shape, embodiments are not limited thereto. The nanostructures NS may be arranged in a hexagonal lattice arrangement or other periodic arrangements.

The nanostructures NS may be made of the same metal material as that of a metal pattern of the device layer DL positioned on the same layer as each layer of the nanostructure layer 500. The nanostructures NS may be formed of a semiconductor material or a dielectric material such as a semiconductor pattern or a dielectric pattern of the device layer DL located on the same layer as each layer of the nanostructure layer 500. Accordingly, the nanostructures NS forming different layers may be formed of different materials. The insulating material around the nanostructures NS may be made of an insulating material used in the insulating pattern provided in the device layer DL located on each layer of the nanostructure layer 500.

The nanostructure layer 500 may transmit fine pattern information of light transmitted through the first alignment key 100 to the second alignment key 200 with little loss. This is because the plurality of fine nanostructures NS act similarly to a waveguide array which guides light in the vertical direction (Z-direction) and the effective refractive index of the nanostructure layer 500 in the horizontal direction (X direction and Y direction) is increased. When light transmitting through the first alignment key 100 travels inside the nanostructure layer 500, light lost in the horizontal direction (X direction or Y direction) may be reduced or minimized, and may reach the second alignment key 200 by proceeding in the vertical direction (Z direction).

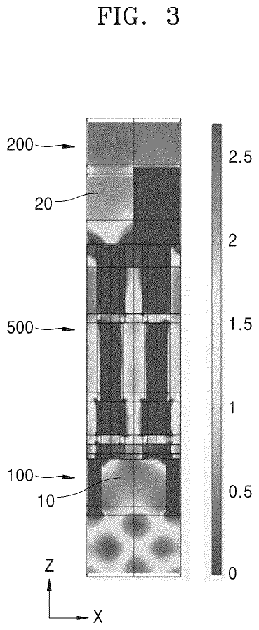

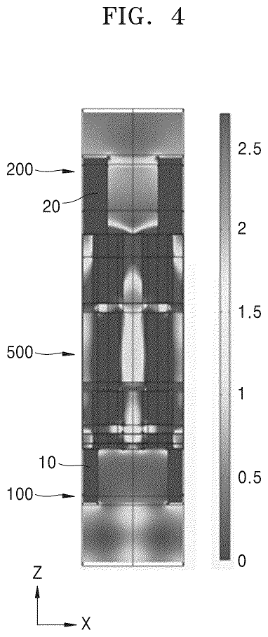

FIGS. 3 and 4 are computer simulation diagrams showing that the transmittance of incident light is classified according to the alignment states of first and second alignment keys of an overlay target structure when manufacturing a device according to an example embodiment.

In the computational simulations of FIGS. 3 and 4, the arrangement pitch p1 of the line masks 10 forming the first alignment key 100 is about 400 nm and the width w1 thereof is 140 nm, and the arrangement pitch p2 of the line masks 20 forming the second alignment key 200 is about 400 nm and the width w2 thereof is about 200 nm. The nanostructure layer 500 includes cylindrical nanostructures NS. This is an example of a unit cell structure having a length of about 400 nm in the X-axis direction at arrangement pitches p1 and p2.

FIGS. 3 and 4 show the transmission patterns of light incident from the top for the misaligned arrangement and aligned arrangement of the line masks 10 and 20 facing each other. FIGS. 3 and 4 are cases in which an alignment error of w212, that is, 100 nm, is mutually provided. FIGS. 3 and 4 respectively confirmed as a state that the first alignment key 100, the nanostructure layer 500, and the second alignment key 200 are aligned to transmit light and aligned to transmit almost no light, by computer simulation results. For example, it may be seen that the overlay target structure OTS of the example embodiment may measure an alignment error of about 100 nm.

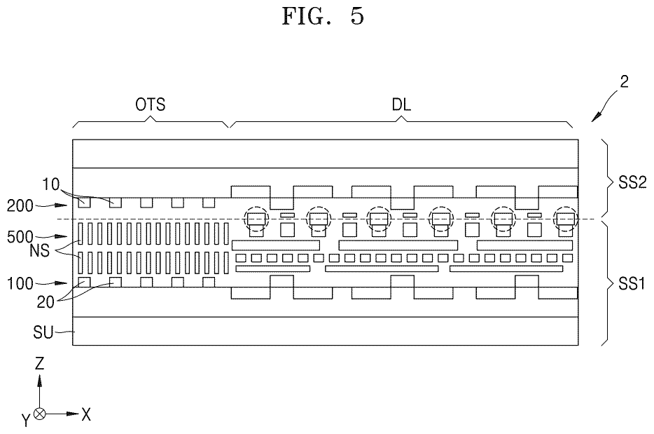

FIG. 5 is a cross-sectional view illustrating a structure of a device according to another example embodiment.

The overlay target structure OTS provided in the device 2 is different from the overlay target structure OTS illustrated in FIG. 1 in that the nanostructure layer 500 has a two-layer structure in the device 2. The device 2 is an example of a structure in which a substrate structure SS1 having a first alignment key 100 and a nanostructure layer 500 and a substrate structure SS2 including a second alignment key SS2 are combined.

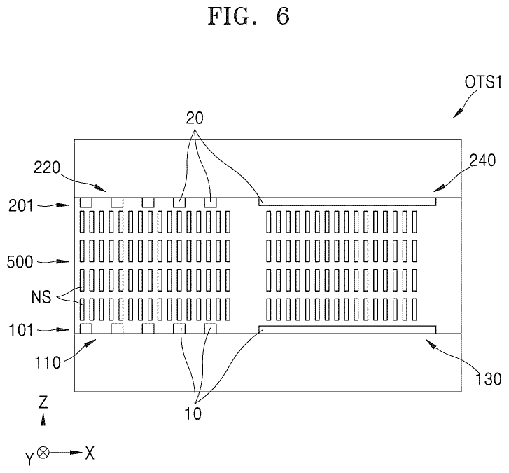

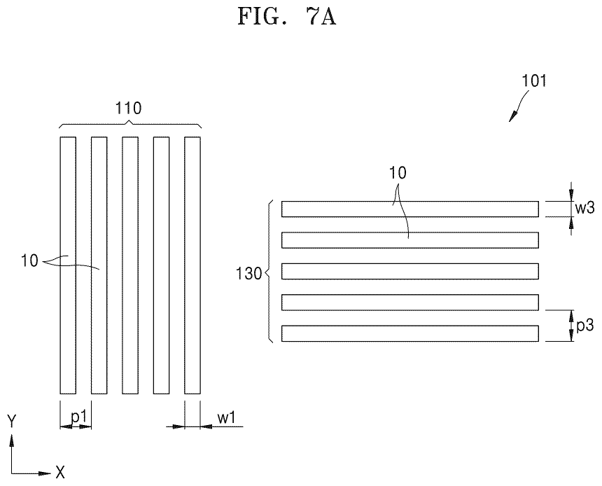

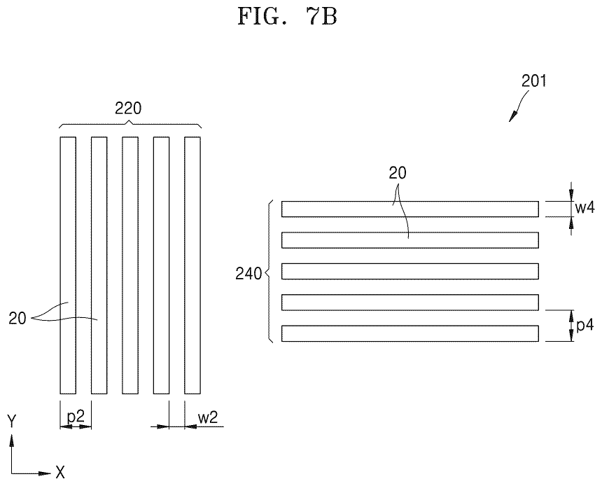

FIG. 6 is a cross-sectional view illustrating an example of an overlay target structure provided in an device according to another example embodiment, and FIGS. 7A and 7B are plan views illustrating respective structures of a first alignment key and a second alignment key of the overlay target structure of FIG. 6.

The overlay target structure OTS1 includes a first alignment key 101, a nanostructure layer 500, and a second alignment key 201.

The first alignment key 101 includes a first pattern 110 and a third pattern 130. The first pattern 110 includes a plurality of line masks 10 that have a length direction of a first direction (Y direction) and a first width w1 in a second direction (X direction), and are arranged at a first pitch p1 in the second direction (X direction). The third pattern 130 includes a plurality of line masks 10 that have a length direction of a second direction (X direction) and a third width w3 in the first direction (Y direction), and are arranged at a third pitch p3 in the first direction (Y direction). The first width w1 and the third width w3 may be the same or different from each other. The first pitch p1 and the third pitch p3 may also be the same or different from each other.

The second alignment key 201 includes a second pattern 220 and a fourth pattern 240. The second pattern 220 includes a plurality of line masks 20 that have a length direction of a first direction (Y direction) and a second width w2 in the second direction (X direction), and are arranged at a second pitch p2 in the second direction (X direction). The fourth pattern 240 includes a plurality of line masks 20 having a length direction in the second direction (X direction) and a fourth width w4 in the first direction (Y direction), and are arranged at a fourth pitch p4 in the first direction (Y direction). The second width w2 and the fourth width w4 may be the same or different from each other. The second pitch p2 and the fourth pitch p4 may also be the same or different from each other. The first width w1 and the second width w2 may be the same or different from each other. The first pitch p1 and the second pitch p2 may be the same or different from each other. For example, the first pitch p1 and the second pitch p2 may be the same, and the first width w1 and the second width w2 may be different. The third pitch p3 and the fourth pitch p4 may be the same, and the third width w3 and the fourth width w4 may be different from each other.

The first pattern 110 and the second pattern 220 form a pair that may measure alignment errors in the second direction (X direction), and the third pattern 130 and the fourth pattern 240 form a pair that may measure alignment errors in the first direction (Y direction).

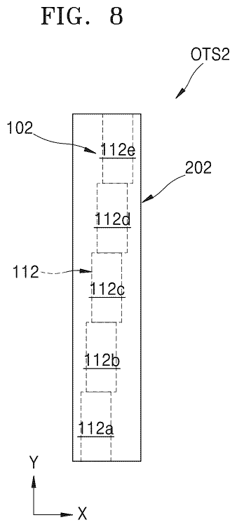

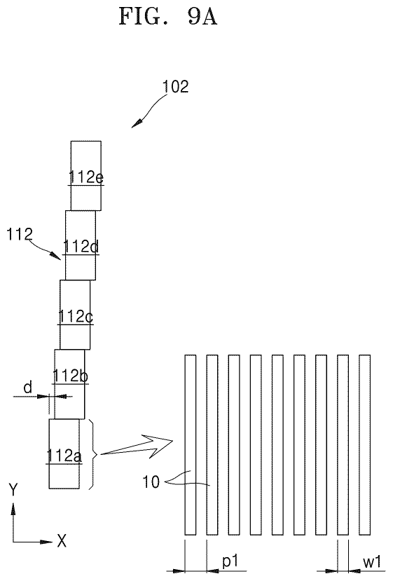

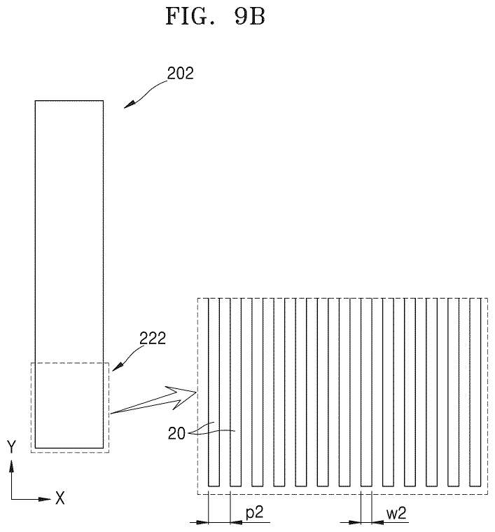

FIG. 8 is a plan view schematically illustrating an overlay target structure provided in a device according to another example embodiment, and FIGS. 9A and 9B are detailed plan views illustrating respective structures of a first alignment key and a second alignment key of the overlay target structure of FIG. 8.

The overlay target structure OTS2 includes a first alignment key 102 and a second alignment key 202, and a nanostructure layer arranged between the first alignment key 102 and the second alignment key 202. Since the nanostructure layer is substantially the same as the nanostructure layer 500 described above, redundant illustration or description thereof will be omitted.

The first alignment key 102 includes a first pattern 112, and the first pattern 112 is divided into a plurality of groups 112a, 112b, 112c, 112d, and 112e. Although the first pattern 112 is illustrated to include five groups, this is only an example and embodiments are not limited thereto. The partitioned size, that is, the length in the first direction (Y direction) of each of the groups 112a to 112e, may be greater than or equal to a reference wavelength, for example, about 1 μm or more. Each of the groups 112a to 112e includes a plurality of line masks 10 that have a length direction of a first direction (Y direction) and a width w1 of a second direction (X direction), and are arranged at a first pitch p1 in the second direction (X direction). The groups 112a to 112e are arranged in the first direction (Y direction), and adjacent groups are arranged to be offset by an interval d in the second direction (X direction).

The groups 112a to 112e are arranged in the first direction (Y direction) in order that the offset interval in the second direction (X direction) gradually increases. For example, the offset intervals of the second group 112b to the fifth group 112e with respect to the first group 112a are d, 2d, 3d, and 4d, respectively.

The second alignment key 202 includes a second pattern 222. The second pattern 222 includes a plurality of line masks 20 that have a length direction of a first direction (Y direction) and a width w2 in the second direction (X direction), and are arranged at a second pitch p2 in the second direction (X direction). The second pattern 222 faces the first pattern 112 shown in FIG. 9A, and the second width w2, second pitch p2, and the number of line masks 20 are set to face the entire plurality of groups 112a to 112e. The number of line masks 10 and the number of line masks 20 are illustrative. The widths w1 and w2 may be the same or different from each other. The pitches p1 and p2 may be the same or different from each other. For example, p1 and p2 may be the same and w1 and w2 may be different.

In the overlay target structure OTS2 as illustrated in FIG. 8, each of the partitioned plurality of groups 112a to 112e included in the first pattern 112 may act like an individual scale for misalignment measurement. For example, the degree of misalignment in the second direction (X direction) may be immediately measured depending on which group is the brightest or darkest pattern among the plurality of groups 112a to 112e.

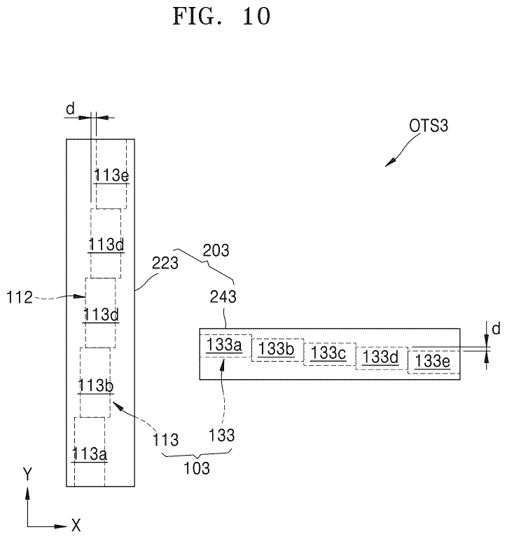

FIG. 10 is a plan view illustrating an overlay target structure provided in a device according to another example embodiment.

The overlay target structure OTS3 as illustrated in FIG. 10 is similar to the overlay target structure OTS2 described in FIGS. 8, 9A and 9B in that it includes a plurality of groups which are sequentially offset-arranged, and differs from the overlay target structure OTS2 described in FIGS. 8, 9A and 9B in that it is the shape capable of measuring the degree of misalignment in two directions of the first direction (Y direction) and the second direction (X direction).

The overlay target structure OTS3 includes a first alignment key 103 and a second alignment key 203. A nanostructure layer is arranged between the first alignment key 103 and the second alignment key 203, and since the nanostructure layer is substantially the same as the nanostructure layer 500 described above, redundant illustration or description thereof will be omitted.

The first alignment key 103 includes a first pattern 113 and a third pattern 133. The first pattern 113 includes a plurality of groups 113a, 113b, 113c, 113d, and 113e, and similar to the first pattern 112 shown in FIG. 9A, each of the groups 113a to 113c includes a plurality of line masks 10 that have a length direction of the first direction (Y direction) and a width w1 in the second direction (X direction) and are arranged at a first pitch p1 in the second direction (X direction). The groups 113a to 113e are arranged in the first direction (Y direction), and adjacent groups are arranged to be offset by an interval d in the second direction (X direction). The third pattern 133 also includes a plurality of groups. The third pattern 133 corresponds to a shape in which the first pattern 112 shown in FIG. 9A is rotated by 90 degrees, that is, each of the groups 133a, 133b, 133c, 133d, and 133e includes a plurality of line masks 10 that have the length direction of the second direction (X direction) and the width w1 of the first direction (Y direction) and are arranged at the first pitch p1 in the first direction (Y direction). The groups 113a to 113e are arranged in the second direction (X direction), and adjacent groups are arranged to be offset by an interval d in the first direction (Y direction).

The second alignment key 203 includes a second pattern 223 and a fourth pattern 243. Similar to the second pattern 222 shown in FIG. 9B, the second pattern 223 includes a plurality of line masks 20 that have the length direction of the second direction (X direction) and the width w2 of the second direction (X direction) and are arranged at the second pitch p2 in the second direction (X direction). The fourth pattern 243 corresponds to a shape in which the second pattern 222 shown in FIG. 9A is rotated by 90 degrees, that is, includes a plurality of line masks 20 that have the length direction of the second direction (X direction) and the width w2 of the first direction (Y direction) and are arranged at the second pitch p2 in the first direction (Y direction).

The second patterns 223 are arranged to face the entire first pattern 113 to form a pair that measures a degree of misalignment in the second direction (X direction). The fourth pattern 243 is arranged to face the entire third pattern 133 to form a pair for measuring a degree of misalignment in the first direction (Y direction).

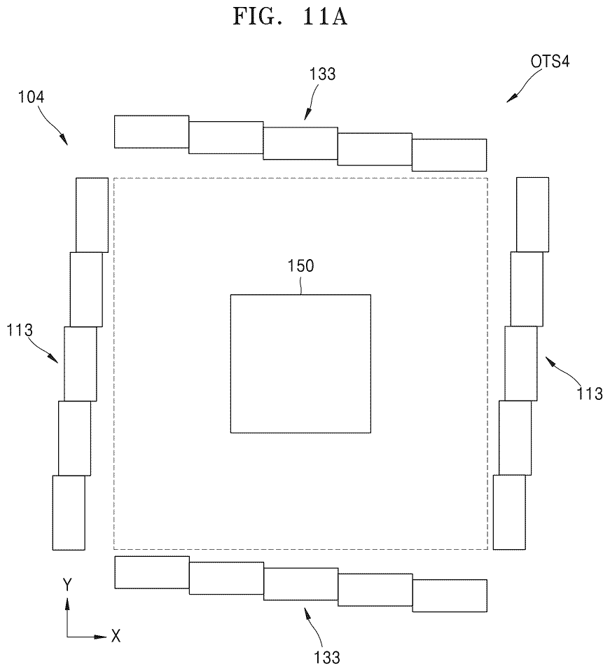

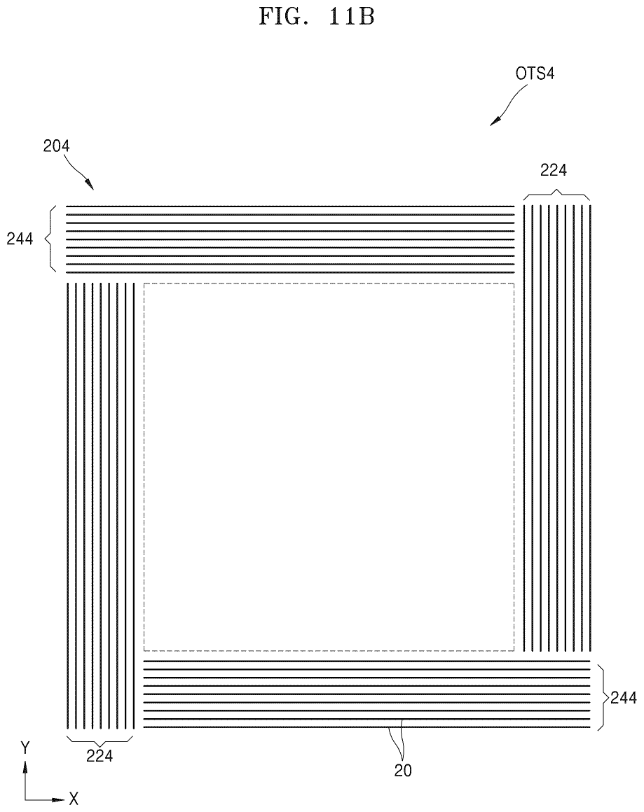

FIGS. 11A and 11B are plan views illustrating a first alignment key and a second alignment key of an overlay target structure provided in a device according to another example embodiment, respectively.

Referring to FIG. 11A, the first alignment key 104 of the overlay target structure OTS4 includes two sets of first patterns 113 and two sets of third patterns 133 described in FIG. 10, and groups provided in each set are arranged in rectangular trajectories. A mask pattern 150 may be further arranged at the center of the region surrounded by and adjacent to the plurality of groups. The mask pattern 150 may be made of a metal material similar to the line masks included in the first pattern 113 and the third pattern 133. The mask pattern 150 may provide a reference for illuminating the overlay target structure OTS4, and may also be omitted.

Referring to FIG. 11B, the second alignment key 204 includes two sets of second patterns 224 and two sets of fourth patterns 244, which are arranged to face the first pattern 113 and the third pattern 133, respectively. Similar to the second pattern 222 described in FIG. 9B, the second pattern 224 includes a plurality of line masks 20 that have a length direction of the first direction (Y direction), and the fourth pattern 244 includes a plurality of line masks 20 that have a length direction of the second direction (X direction).

The size of the horizontal cross section (XY plane) of the overlay target structure OTS4 may be approximately 20 μm×20 μm to 300 μm×300 μm. For example, the number of groups of the first alignment keys 104 arranged in the first direction (Y direction) and the second direction (X direction) may be approximately 20 to 300. However, embodiments are not limited thereto.

In this way, the plurality of groups of the first alignment key 104 provided in the overlay target structure OTS4 may act as a two-dimensional scale to measure the degree of misalignment. For example, depending on the location of the group representing the brightest or darkest pattern, the degree of misalignment in the first direction (Y direction) and the second direction (X direction) may be easily measured.

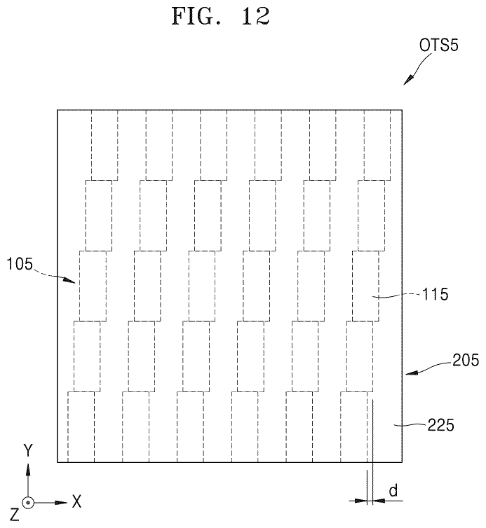

FIGS. 12 to 14 are plan views illustrating overlay target structures provided in a device according to other example embodiments, respectively.

Referring to FIG. 12, the overlay target structure OTS5 includes a first alignment key 105 and a second alignment key 205. The first alignment key 105 and the second alignment key 205 are spaced apart from each other in the Z direction. A nanostructure layer is arranged between the first alignment key 105 and the second alignment key 205, and since the nanostructure layer is substantially the same as the nanostructure layer 500 described above, redundant illustration or description thereof will be omitted.

The first alignment key 105 includes a plurality of groups 115. The plurality of groups 115 are similar to the groups forming the first pattern 112 described in FIG. 9A. For example, each of the plurality of groups 115 includes a plurality of line masks 10 that have a length direction of a first direction (Y direction) and a width w1 of a second direction (X direction), and are arranged at a first pitch p1 in the second direction (X direction). The groups 115 are arranged in the first direction (Y direction), and adjacent groups are arranged to be offset by a predetermined interval d in the second direction (X direction), forming a vertical column. A plurality of vertical columns are arranged at predetermined intervals in the X direction. The number of vertical columns is shown as six, but this is only an example and of the number of columns may be two or more. In addition, the number of groups 115 included in one vertical column is illustrative, and the number of groups is not limited to the illustrated number.

For example, the first alignment key 105 corresponds to a form in which a plurality of first patterns 112 as described in FIG. 9A are arranged at predetermined intervals in the X direction. When the number of groups 115 included in one vertical column is N, the interval spaced apart in the second direction (X direction) of the vertical columns formed by the groups 115 arranged in the first direction (Y direction) may be N*d or more, for example, (N+1)*d. For example, the pitch at which the vertical columns are repeatedly arranged in the horizontal direction may be greater than or equal to (M*p1+w1)+N*d. Here, (M*p1+w1) is the horizontal width of the group 115, and M is the number of line masks 10 included in the group 115. However, embodiments are not limited thereto.

The second alignment key 205 includes a second pattern 225. Similar to the second pattern 222 shown in FIG. 9B, the second pattern 225 includes a plurality of line masks 20 that have the length direction of the second direction (X direction) and the width w2 of the second direction (X direction) and are arranged at the second pitch p2 in the second direction (X direction). In the second pattern 225, the second width w2, the second pitch p2, and the number of line masks 20 are set to face the entire plurality of groups 115 included in the first alignment key 105.

This type of overlay target structure OTS5 may be used to measure misalignment in the X direction in more detail and accurately.

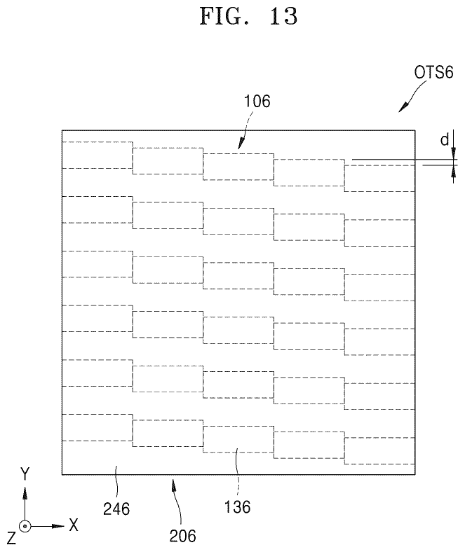

Referring to FIG. 13, the overlay target structure OTS6 includes a first alignment key 106 and a second alignment key 206. The first alignment key 106 and the second alignment key 206 are spaced apart from each other in the Z direction, and a nanostructure layer is arranged between the first alignment key 106 and the second alignment key 206.

The first alignment key 106 includes a plurality of groups 136, and each of the plurality of groups 136 has a length direction of the X direction and includes a plurality of line masks arranged in the Y direction. The second alignment key 206 includes a fourth pattern 246, and the fourth pattern 246 includes a plurality of line masks having a length direction of X direction and arranged in the Y direction.

The overlay target structure OTS6 according to the example embodiment corresponds to a shape in which the overlay target structure OTS5 of FIG. 12 rotates by 90 degrees, that is, may be used to measure misalignment in the Y direction in more detail and accurately.

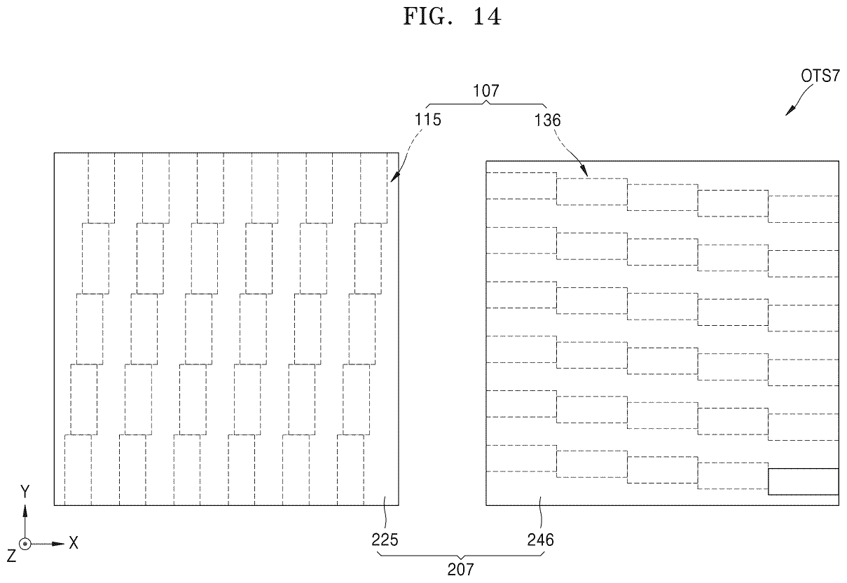

Referring to FIG. 14, an overlay target structure OTS7 includes a first alignment key 107, a second alignment key 207, and a nanostructure layer between the first alignment key 107 and the second alignment key 207. The overlay target structure OTS7 of this example embodiment corresponds to a combination of the overlay target structure OTS5 of FIG. 12 and the overlay target structure OTS6 of FIG. 13. For example, the first alignment key 107 includes a plurality of groups 115 consisting of a plurality of line masks with a length direction of the Y direction, and a plurality of groups 136 consisting of a plurality of line masks with a length direction of the X direction, and the second alignment key 207 includes a second pattern 225 including a plurality of line masks with a length direction of the Y direction, and a fourth pattern 246 including a plurality of line masks with a length direction of the X direction.

This type of overlay target structure OTS7 may be used to measure misalignment in the X direction and misalignment in the Y direction in more detail and accurately.

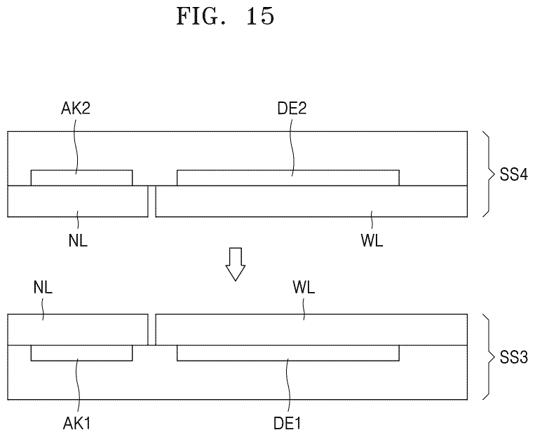

FIGS. 15 to 18 are diagrams illustrating examples in which overlay target structures according to example embodiments are used.

Referring to FIG. 15, face to face bonding of two substrate structures SS3 and SS4 is illustrated. The substrate structure SS3 includes a device DE1, a first alignment key AK1, and a nanostructure layer NL, and the substrate structure SS3 includes a device DE2 and a second alignment key AK2. Furthermore, a wiring layer WL equipped with metal wirings for driving and coupling the two devices DE1 and DE2 may be formed on each of the substrate structures SS3 and SS4.

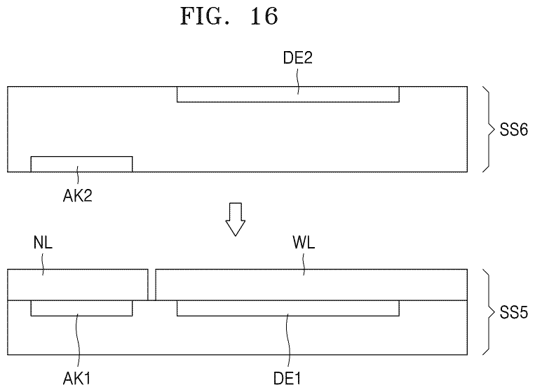

Referring to FIG. 16, face to face bonding of two substrate structures SS5 and SS6 is illustrated. The substrate structure SS5 includes a device DE1, a first alignment key AK1, and a nanostructure layer NL, and the substrate structure SS6 includes a device DE2 and a second alignment key AK2. A wiring layer WL equipped with metal wirings for driving and coupling the two devices DE1 and DE2 may be formed on the substrate structure SS5.

In FIGS. 15 and 16, a first alignment key AK1, a second alignment key AK2, and a nanostructure layer NL may include the first alignment key 100, 101, 102, 103, 104, 105, 106, or 107, the second alignment key 200, 201, 202, 203, 204, 205, 206, or 207, and the nanostructure layer 500) of various examples described above.

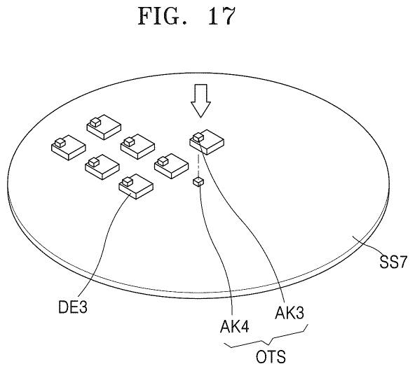

FIG. 17 shows that a device DE3 having an alignment key AK3 is bonded on a substrate structure SS7 having an alignment keys AK4. The substrate structure SS7 may include devices and wirings.

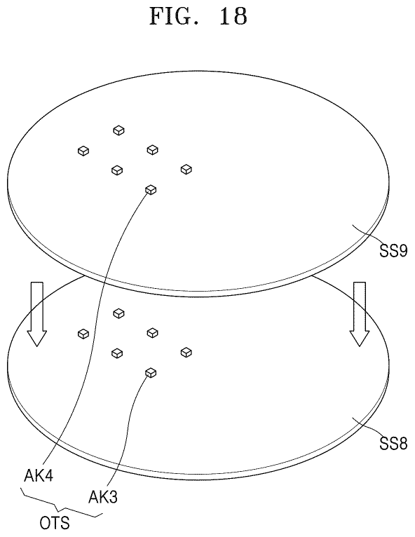

FIG. 18 shows that the substrate structure SS8 including the alignment keys AK3 and the substrate structure SS9 including the alignment keys AK4 are bonded. The substrate structure SS8 and SS9 may include devices and wirings.

In FIGS. 17 and 18, the alignment keys AK3 and AK4 may include the first alignment keys 100, 101, 102, 103, 104, 105, 106, or 107 and the second alignment keys 200, 201, 202, 203, 204, 205, 206, or 207, and any one of the alignment keys AK3 and AK4 may include the aforementioned nanostructure layer 500. For example, the overlay target structure OTS composed of the two alignment keys AK3 and AK4 may be one of the overlay target structures OTS1, OTS2, OTS3, OTS4, OTS5, OST6, and OTS7 described above.

The overlay target structure described above has a structure capable of more precisely measuring alignment errors in the manufacture of stacking of various electronic and optical devices, and thus a device including the same may have improved precision.

It should be understood that embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. A device comprising:
a substrate; and
an overlay target structure provided on the substrate,
wherein the overlay target structure comprises:
a first alignment key having a first pattern that comprises a plurality of first line masks arranged at a first pitch in a second direction, each first line mask of the plurality of first line masks having a first width in the second direction and a first length in a first direction perpendicular to the second direction;
a second alignment key spaced apart from the first alignment key in a third direction perpendicular to the first direction and the second direction to face the first alignment key, and having a second pattern that comprises a plurality of second line masks arranged at a second pitch in the second direction, each second line mask of the plurality of second line masks having a second width in the second direction and a second length in the first direction; and
a nanostructure layer comprising a plurality of nanostructures between the first alignment key and the second alignment key, each nanostructure of the plurality of nanostructures having a width that is less than or equal to the first width and the second width and being arranged at a pitch that is less than the first pitch and the second pitch.

2. The device of claim 1, wherein the plurality of nanostructures comprise a metal material or a dielectric material.

3. The device of claim 1, wherein each nanostructure of the plurality of nanostructures has a cylindrical shape or a polygonal pillar shape, and
wherein a cross-section diameter or one side of each nanostructure of the plurality of nanostructures is less than or equal to the first width and the second width.

4. The device of claim 1, wherein the plurality of nanostructures are provided in at least two layers arranged in the third direction.

5. The device of claim 4, wherein an interval between adjacent layers among the at least two layers is less than or equal to 100 nm.

6. The device of claim 1, wherein each first line mask of the plurality of first line masks and each second line mask of the plurality of second line masks comprises a metal material.

7. The device of claim 1, wherein the first pattern comprises a plurality of first groups, each first group of the plurality of first groups comprising the plurality of first line masks, and
wherein the plurality of first groups are arranged in the first direction, and adjacent groups of the plurality of first groups are offset at a predetermined interval in the second direction with respect to each other.

8. The device of claim 7, wherein the plurality of first groups are arranged in the first direction and gradually offset in the second direction.

9. The device of claim 7, wherein the predetermined interval is less than or equal to ½ of the first width.

10. The device of claim 7, wherein the predetermined interval is less than or equal to 100 nm.

11. The device of claim 7, wherein a size of each first group of the plurality of first groups in the first direction is greater than or equal to 1 μm.

12. The device of claim 1, wherein the first alignment key further comprises a third pattern on a same layer as the first pattern, the third pattern comprising a plurality of third line masks arranged at a third pitch in the first direction, each third line mask of the plurality of third line masks having a third length in the second direction and a third width in the first direction, and
wherein the second alignment key further comprises a fourth pattern on a same layer as the second pattern, the fourth pattern comprising a plurality of fourth line masks arranged at a fourth pitch in the first direction, each fourth line mask of the plurality of fourth line masks having a fourth length in the second direction and a fourth width in the first direction.

13. The device of claim 12, wherein the first pattern comprises a plurality of first groups, each first group of the plurality of first groups comprising the plurality of first line masks, and
wherein the plurality of first groups are arranged in the first direction, and adjacent groups of the plurality of first groups are offset at a predetermined interval in the second direction with respect to each other.

14. The device of claim 13, wherein the third pattern comprises a plurality of third groups, each third group of the plurality of third groups comprising the plurality of third line masks, and
wherein the plurality of third groups are arranged in the second direction, and adjacent groups of the plurality of third groups are offset at a predetermined interval in the first direction with respect to each other.

15. The device of claim 14, wherein the plurality of first groups included in the first pattern form a first set, and the plurality of third groups included in the third pattern key form a third set,
wherein the first alignment key further comprises a second set comprising a plurality of second groups having a configuration same as the first set and a fourth set comprising a plurality of fourth groups having a configuration same as the third set, and
wherein a trajectory in which the plurality of first groups included in the first set, the plurality of second groups included in the second set, the plurality of third groups included in the third set, and the plurality of fourth groups included in the fourth set are arranged is rectangular.

16. The device of claim 15, wherein the first alignment key further comprises a mask pattern in a central portion of a rectangular trajectory formed by the first set, the second set, the third set, and the fourth set.

17. A device comprising:
a substrate;
a first alignment key having a first pattern that comprises a plurality of first line masks arranged at a first pitch in a second direction, each first line mask of the plurality of first line masks having a first width in the second direction and a first length in a first direction perpendicular to the second direction; and
a nanostructure layer comprising a plurality of nanostructures provided on the first alignment key, each nanostructure of the plurality of nanostructures having a width that is less than the first width and arranged at a pitch less than the first pitch.

18. The device of claim 17, wherein the first alignment key further comprises a third pattern on a same layer as the first pattern, and comprises a plurality of third line masks arranged at a third pitch in the first direction, each third line mask of the plurality of third line masks having a third length in the second direction and a third width in the first direction.

19. The device of claim 18, wherein the first pattern comprises a plurality of first groups, each first group of the plurality of first groups which has the plurality of first line masks, and
wherein the plurality of first groups are arranged in the first direction, and adjacent groups of the plurality of first groups are offset at a predetermined interval in the second direction with respect to each other.

20. The device of claim 19, wherein the third pattern comprises a plurality of third groups, each third group of the plurality of third groups has the plurality of third line masks, and
wherein the plurality of third groups are arranged in the second direction, and adjacent groups of the plurality of third groups are offset at a predetermined interval in the first direction with respect to each other.
